(19) United States
(12) Patent Application Publication
(10) Pub. No.: US 2013/0279869 A1
(43) Pub. Date: Oct. 24, 2013

(54) PLANAR OPTICAL WAVEGUIDE AND METHOD FOR MAKING SAME

(71) Applicant: HSIN-SHUN HUANG, Tu-Cheng (TW)

(72) Inventor: HSIN-SHUN HUANG, Tu-Cheng (TW)

(73) Assignee: HON HAI PRECISION INDUSTRY CO., LTD., Tu-Cheng (TW)

(21) Appl. No.: 13/600,122

(22) Filed: Aug. 30, 2012

(30) Foreign Application Priority Data
Apr. 20, 2012 (TW) 101114253

(51) Int. Cl. G02B 6/10; G03F 7/20

(52) U.S. Cl. 385/129; 430/321

(57) ABSTRACT

A planar optical waveguide includes a trunk, and a first branch and a second branch each extending from the trunk in a manner that the first branch and the second branch cooperatively form a division. The trunk, the first branch and the second branch are located at a same plane. The trunk defines a butt end surface at the division, and the first and second branches are connected by the butt end surface. A method for making the planar optical waveguide is also provided.

### BACKGROUND

1. Technical Field

The present disclosure relates to planar optical waveguides, and particularly to a 1×2 planar optical waveguide and a method for making same.

2. Description of Related Art

Planar optical waveguides including 1×2 types or 1×N types, are used as light coupling or light division elements. In an application example, a planar optical waveguide can couple light beams with different wavelengths to an optical fiber, and can divide light from the optical fiber into light beams with different wavelengths.

In order to reduce light loss, 1×2 planar optical waveguides such as a Y type planar optical waveguide simply controls a subtended angle of ends of “Y” within 1 degree. However, the subtended angle within 1 degree makes the fabrication of the 1×2 planar optical waveguide difficult, and various product defects, such as a split, a void or an unwanted angle may occur.

What is needed, therefore, is a planar optical waveguide and a method for making same, which can overcome the above shortcomings.

### BRIEF DESCRIPTION OF THE DRAWINGS

Many aspects of the present planar optical waveguide and method can be better understood with reference to the following drawings. The components in the drawings are not necessarily drawn to scale, the emphasis instead being placed upon clearly illustrating the principles of the present planar optical waveguide and method. Moreover, in the drawings, like reference numerals designate corresponding parts throughout the several views.

FIG. 1 is a schematic isometric view of a planar optical waveguide in accordance with a first embodiment.

FIG. 2 is a schematic isometric view of a planar optical waveguide in accordance with a second embodiment.

FIG. 3 shows a light transmitting substrate and a mask used to make the planar optical waveguide of FIG. 2 in accordance with an embodiment.

FIG. 4 shows steps of a method for making the planar optical waveguide of FIG. 2.

### DETAILED DESCRIPTION

Embodiments of the present planar optical waveguide and method will be described with reference to the drawings.

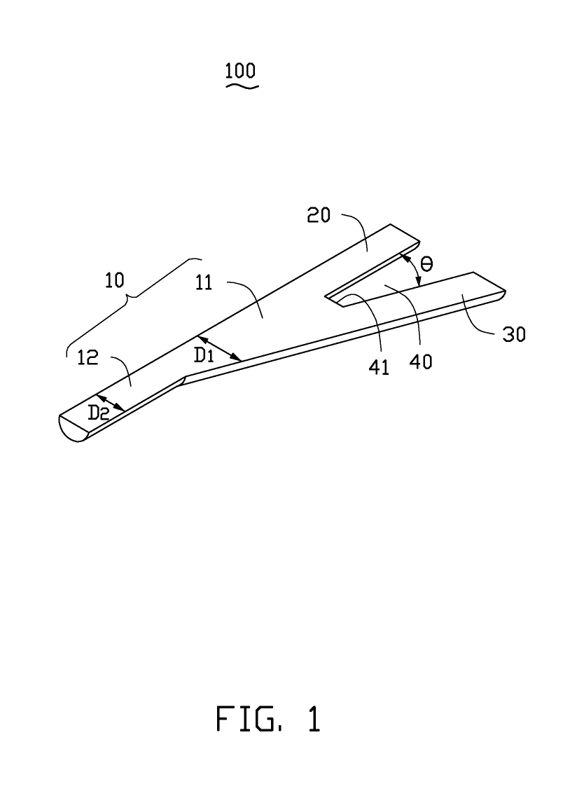

Referring to FIG. 1, a planar optical waveguide 100 in accordance with a first embodiment is shown. The planar optical waveguide 100 includes a trunk 10, and a first branch 20 and a second branch 30 each extending from the trunk 10. The trunk 10, the first branch 20 and the second branch 30 are located on a same plane. The first branch 20 and the second branch 30 cooperatively form a division 40. The planar optical waveguide 100 is a 1×2 planar optical waveguide, and is substantially a Y type.

The trunk 10 defines a butt end surface 41 at the division 40, and the first branch 20 and the second branch 30 are connected by the butt end surface 41. In the present embodiment, the butt end surface 41 is a flat surface. In other embodiment, the butt end surface 41 may be a curved surface.

The butt end surface 41 avoids the division 40 being a very sharp corner or edge, such that the fabrication of the planar optical waveguide 100 is much easier, and various product defects, such as a split, a void or an unwanted angle at the division 40, which promote light loss, can be reduced or avoided. The butt end surface 41 has a certain area, and the area can be decided by its relationship to an acceptable light loss percentage at the division 40.

The first branch 20 and the second branch 30 are spaced from each other a certain distance, and subtend an angle θ. The subtended angle θ may be within 1 degree, which contributes to less light loss.

The trunk 10 includes a first section 11 adjacent to the first and second branches 20 and 30, and a second section 12 connected to the first section 11. A central axis of the second section 12 aligns with that of the first branch 20. A width D₂ of a cross section of the second section 12 is constant, and a width D₁ of a cross section of the first section 11 gradually increases as it comes closer to the butt end surface 41, and the width D₁ of the first section 11 is greater than the width D₂ of the second section 12.

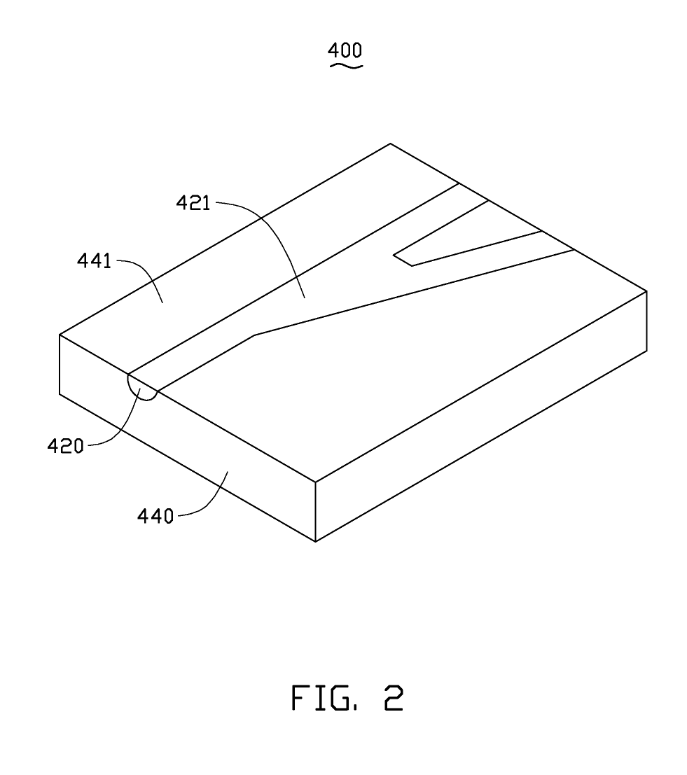

Referring to FIG. 2, a planar optical waveguide 400 in accordance with a second embodiment is shown. The planar optical waveguide 400 includes a substrate 440 and a guiding layer 420 formed in the substrate 440. The substrate 440 contains a material selected from silicon and lithium niobate, and the guiding layer 420 contains a material selected from titanium, zinc and nickel. The shape of the guiding layer 420 is essentially the same as that of the planar optical waveguide 100. In the present embodiment, a top surface 421 of the guiding layer 420 is planar with a top surface 441 of the substrate 440, and opposite ends of the guiding layer 420 are exposed at opposite ends of the substrate 440.

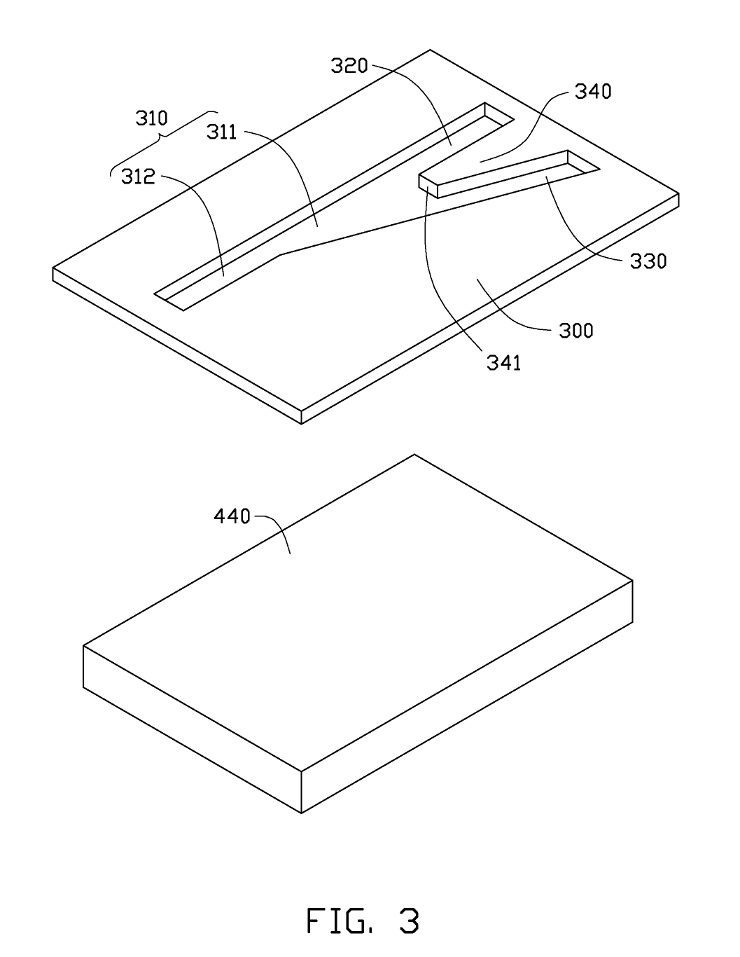

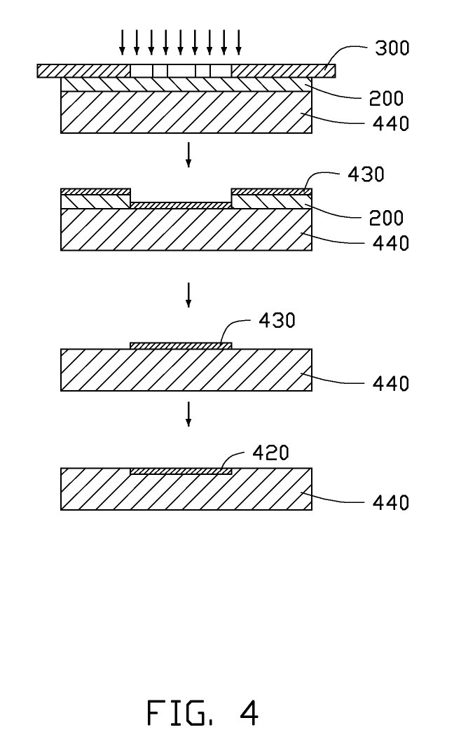

Referring to FIGS. 3 and 4, a method for making the planar optical waveguide 400 in accordance with an embodiment is provided. The method may follow the following steps.

First, a substrate 440 and a mask 300 having a pattern of the guiding layer 420 are provided. The substrate 440 contains a material selected from silicon and lithium niobate.

In the present embodiment, the guiding layer 420 takes its form from the mask 300, such that the mask 300 includes a trunk hole section 310, and a first branch hole section 320 and a second branch hole section 330 extending from the trunk hole section 310. The trunk hole section 310 includes a first hole section 311 adjacent to the first branch hole section 320 and the second branch hole section 330, and a second hole section 312 in communication with the first hole section 311. A protrusion 340 is located between the first branch hole section 320 and the second branch hole section 330, and a flat distal end surface 341 is defined at the end of the protrusion 340 to form the butt end surface 41 of the guiding layer 420.

Second, a photo-resist layer 200 is formed on the substrate 440.

Third, the mask 300 is applied on the photo-resist layer 200, and the pattern of the guiding layer 420 is transferred on the substrate 440 using a photo lithography process. In detail, the photo lithography process may include exposing to photolight, baking, and developing, thereby transferring the pattern of the guiding layer 420 on the substrate 440.

Fourth, a refracting material film 430 is formed on both the substrate 440 and a remaining photo-resist layer 200 on the substrate 440. The refracting material can be selected from titanium, zinc and nickel.

Fifth, the remaining photo-resist layer 200 with the refracting material film 430 thereon is removed, remaining the refracting material film 430 with the pattern of the guiding layer 420 on the substrate 440.

Finally, the substrate 440 is heated to diffuse the refracting material in the substrate 440, thereby forming the guiding layer 420 in the substrate 440, and the planar optical waveguide 400 is thus formed. The refracting material can be doped in the material of the substrate 440 by diffusing, thus forming the guiding layer 420.

The mask 300 can also be made by a photo lithography process.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A planar optical waveguide, comprising:
a trunk; and
a first branch and a second branch each extending from the trunk in a manner that the first branch and the second branch cooperatively form a division, the trunk, the first branch and the second branch being located on a same plane, the trunk defining a butt end surface at the division, and the first and second branches being connected by the butt end surface.

2. The planar optical waveguide of claim 1, wherein the first and second branches subtend an angle within 1 degree.

3. The planar optical waveguide of claim 1, wherein the butt end surface is a flat surface.

4. The planar optical waveguide of claim 1, wherein the trunk comprises a first section adjacent to the end surface, and a second section connected to the first section, a width of a cross section of the first section is greater than that of the second section, a width of a cross section of the second section is constant, and the width of the cross section of the first section gradually increases in a direction toward the butt end surface.

5. The planar optical waveguide of claim 4, wherein a central axis of the second section is aligned with that of the first section.

6. The planar optical waveguide of claim 1, wherein each of the first branch and the second branch is straight.

7. A planar optical waveguide comprising:
a substrate; and
a guiding layer formed in the substrate, the guiding layer comprising:
a trunk; and
a first branch and a second branch each extending from the trunk in a manner that the first branch and the second branch cooperatively form a division, the trunk, the first branch and the second branch being located on a same plane, the trunk defining a butt end surface at the division, and the first and second branches being connected by the butt end surface.

8. The planar optical waveguide of claim 7, wherein the first and second branches subtend an angle within 1 degree.

9. The planar optical waveguide of claim 7, wherein the butt end surface is a flat surface.

10. The planar optical waveguide of claim 7, wherein the substrate contains a material selected from silicon and lithium niobate, and the guiding layer contains a material selected from titanium, zinc and nickel.

11. A method for making a planar optical waveguide of claim 7, the method comprising:
providing a substrate and a mask having a pattern conforming to the shape of the guiding layer;
forming a photo-resist layer on the substrate;
applying the mask on the photo-resist layer and transferring the pattern of the guiding layer in the photo-resist layer on the substrate using a photo lithography process;
forming a refracting material film on the substrate; and
heating the substrate to diffuse the refracting material in the substrate, thereby forming the guiding layer in the substrate.

12. The method of claim 11, wherein the substrate contains a material selected from silicon and lithium niobate, and the refracting material is selected from a group consisting of titanium, zinc and nickel.

13. The method of claim 11, wherein the pattern of the guiding layer is hollowed out in the mask in a manner that the mask comprises a trunk hole section, a first branch hole section and a second branch hole section each extending from and in communication with the trunk hole section, and a protrusion located between the first branch hole section and the second branch hole section, the protrusion having a distal end surface to form the butt end surface at the division of the planar optical waveguide.
